(19) United States
(12) Patent Application Publication
(10) Pub. No.: US 2025/0098245 A1
(43) Pub. Date: Mar. 20, 2025

(54) SOURCE/DRAIN REGIONS FOR NANOSHEET DEVICES

(71) Applicant: International Business Machines Corporation, Armonk, NY (US)

(72) Inventors: Sagarika Mukesh, Albany, NY (US); Alexander Reznicek, Troy, NY (US); Tao Li, Slingerlands, NY (US); Ruilong Xie, Niskayuna, NY (US)

(21) Appl. No.: 18/470,669

(22) Filed: Sep. 20, 2023

(51) Int. Cl. H01L 29/08; H01L 21/02; H01L 23/528; H01L 29/06; H01L 29/40; H01L 29/417; H01L 29/423; H01L 29/66; H01L 29/775

(52) U.S. Cl. CPC H10D 62/151; H01L 21/02532; H01L 21/02609; H01L 23/5286; H10D 30/014; H10D 30/43; H10D 30/6729; H10D 30/6735; H10D 62/121; H10D 64/01

(57) ABSTRACT

A semiconductor device comprises a stacked structure, the stacked structure comprising a plurality of gate structures alternately stacked with a plurality of channel layers. At least one epitaxial source/drain region disposed on a side of the stacked structure, and the stacked structure is disposed on at least one dielectric layer. A portion of the at least one epitaxial source/drain region is disposed in the at least one dielectric layer.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming source/drain regions for nanosheet transistors.

In one embodiment, a semiconductor device comprises a stacked structure, the stacked structure comprising a plurality of gate structures alternately stacked with a plurality of channel layers. At least one epitaxial source/drain region disposed on a side of the stacked structure, and the stacked structure is disposed on at least one dielectric layer. A portion of the at least one epitaxial source/drain region is disposed in the at least one dielectric layer.

In another embodiment, a semiconductor device comprises a first nanosheet structure comprising a first plurality of gate structures alternately stacked with a first plurality of channel layers, and a second nanosheet structure comprising a second plurality of gate structures alternately stacked with a second plurality of channel layers. At least one epitaxial source/drain region is disposed between the first and second nanosheet structures. The first and second nanosheet structures are disposed on at least one dielectric layer, wherein a portion of the at least one epitaxial source/drain region is disposed in the at least one dielectric layer.

In another embodiment, a method comprises forming a stacked structure comprising a plurality of sacrificial semiconductor layers alternately stacked with a plurality of channel layers. The stacked structure is formed on a semiconductor layer comprising a surface with a designated crystal orientation. In the method, at least one epitaxial source/drain region is grown on a side of the stacked structure from an exposed portion of the semiconductor layer in a bottom-up epitaxial growth process.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure with lines X, Y1 and Y2 on which the cross-sectional views of FIGS. 2A-11C are based, according to an embodiment of the invention.

FIG. 2A depicts a first cross-sectional view corresponding to the line X in FIG. 1 illustrating semiconductor nanosheet layers, according to an embodiment of the invention.

FIG. 2B depicts a second cross-sectional view corresponding to the line Y1 in FIG. 1 illustrating semiconductor nanosheet layers, according to an embodiment of the invention.

FIG. 2C depicts a third cross-sectional view corresponding to the line Y2 in FIG. 1 illustrating semiconductor nanosheet layers, according to an embodiment of the invention.

FIG. 3A depicts a first cross-sectional view corresponding to the line X in FIG. 1 following nanosheet layer patterning and isolation region formation, according to an embodiment of the invention.

FIG. 3B depicts a second cross-sectional view corresponding to the line Y1 in FIG. 1 following nanosheet layer patterning and isolation region formation, according to an embodiment of the invention.

FIG. 3C depicts a third cross-sectional view corresponding to the line Y2 in FIG. 1 following nanosheet layer patterning and isolation region formation, according to an embodiment of the invention.

FIG. 4A depicts a first cross-sectional view corresponding to the line X in FIG. 1 following dummy gate formation, according to an embodiment of the invention.

FIG. 4B depicts a second cross-sectional view corresponding to the line Y1 in FIG. 1 following dummy gate formation, according to an embodiment of the invention.

FIG. 4C depicts a third cross-sectional view corresponding to the line Y2 in FIG. 1 following dummy gate formation, according to an embodiment of the invention.

FIG. 5A depicts a first cross-sectional view corresponding to the line X in FIG. 1 following recessing of exposed portions of isolation regions, according to an embodiment of the invention.

FIG. 5B depicts a second cross-sectional view corresponding to the line Y1 in FIG. 1 following recessing of exposed portions of isolation regions, according to an embodiment of the invention.

FIG. 5C depicts a third cross-sectional view corresponding to the line Y2 in FIG. 1 following recessing of exposed portions of isolation regions, according to an embodiment of the invention.

FIG. 6A depicts a first cross-sectional view corresponding to the line X in FIG. 1 following selective removal of a sacrificial semiconductor layer, according to an embodiment of the invention.

FIG. 6B depicts a second cross-sectional view corresponding to the line Y1 in FIG. 1 following selective removal of a sacrificial semiconductor layer, according to an embodiment of the invention.

FIG. 6C depicts a third cross-sectional view corresponding to the line Y2 in FIG. 1 following selective removal of a sacrificial semiconductor layer, according to an embodiment of the invention.

FIG. 7A depicts a first cross-sectional view corresponding to the line X in FIG. 1 following gate spacer formation, bottom dielectric insulator layer (BDI) formation, lateral recessing of sacrificial semiconductor layers and inner spacer formation, according to an embodiment of the invention.

FIG. 7B depicts a second cross-sectional view corresponding to the line Y1 in FIG. 1 following gate spacer formation, bottom dielectric insulator layer (BDI) formation, lateral recessing of sacrificial semiconductor layers and inner spacer formation, according to an embodiment of the invention.

FIG. 7C depicts a third cross-sectional view corresponding to the line Y2 in FIG. 1 following gate spacer formation, bottom dielectric insulator (BDI) layer formation, lateral recessing of sacrificial semiconductor layers and inner spacer formation, according to an embodiment of the invention.

FIG. 8A depicts a first cross-sectional view corresponding to the line X in FIG. 1 following removal of exposed portions of the BDI layer and the underlying semiconductor layer, according to an embodiment of the invention.

FIG. 8B depicts a second cross-sectional view corresponding to the line Y1 in FIG. 1 following removal of exposed portions of the BDI layer and the underlying semiconductor layer, according to an embodiment of the invention.

FIG. 8C depicts a third cross-sectional view corresponding to the line Y2 in FIG. 1 following removal of exposed portions of the BDI layer and the underlying semiconductor layer, according to an embodiment of the invention.

FIG. 9A depicts a first cross-sectional view corresponding to the line X in FIG. 1 following epitaxial source/drain region formation, according to an embodiment of the invention.

FIG. 9B depicts a second cross-sectional view corresponding to the line Y1 in FIG. 1 following epitaxial source/drain region formation, according to an embodiment of the invention.

FIG. 9C depicts a third cross-sectional view corresponding to the line Y2 in FIG. 1 following epitaxial source/drain region formation, according to an embodiment of the invention.

FIG. 10A depicts a first cross-sectional view corresponding to the line X in FIG. 1 following inter-layer dielectric (ILD) layer formation and planarization, according to an embodiment of the invention.

FIG. 10B depicts a second cross-sectional view corresponding to the line Y1 in FIG. 1 following ILD layer formation and planarization, according to an embodiment of the invention.

FIG. 10C depicts a third cross-sectional view corresponding to the line Y2 in FIG. 1 following ILD layer formation and planarization, according to an embodiment of the invention.

FIG. 11A depicts a first cross-sectional view corresponding to the line X in FIG. 1 following dummy gate and sacrificial semiconductor layer removal, according to an embodiment of the invention.

FIG. 11B depicts a second cross-sectional view corresponding to the line Y1 in FIG. 1 following dummy gate and sacrificial semiconductor layer removal, according to an embodiment of the invention.

FIG. 11C depicts a third cross-sectional view corresponding to the line Y2 in FIG. 1 following dummy gate and sacrificial semiconductor layer removal, according to an embodiment of the invention.

FIG. 12 depicts the top view of a semiconductor structure with lines X, Y1 and Y2 on which the cross-sectional views of FIGS. 13A-20C are based, according to an embodiment of the invention.

FIG. 13A depicts a first cross-sectional view corresponding to the line X in FIG. 12 following replacement metal gate (RMG) and gate cut formation, according to an embodiment of the invention.

FIG. 13B depicts a second cross-sectional view corresponding to the line Y1 in FIG. 12 following RMG and gate cut formation, according to an embodiment of the invention.

FIG. 13C depicts a third cross-sectional view corresponding to the line Y2 in FIG. 12 following RMG and gate cut formation, according to an embodiment of the invention.

FIG. 14A depicts a first cross-sectional view corresponding to the line X in FIG. 12 following middle-of-line (MOL) contact formation, back-end-of-line (BEOL) interconnect formation and carrier wafer bonding, according to an embodiment of the invention.

FIG. 14B depicts a second cross-sectional view corresponding to the line Y1 in FIG. 12 following MOL contact formation, BEOL interconnect formation and carrier wafer bonding, according to an embodiment of the invention.

FIG. 14C depicts a third cross-sectional view corresponding to the line Y2 in FIG. 12 following MOL contact formation, BEOL interconnect formation and carrier wafer bonding, according to an embodiment of the invention.

FIG. 15A depicts a first cross-sectional view corresponding to the line X in FIG. 12 following wafer flipping and semiconductor substrate removal, according to an embodiment of the invention.

FIG. 15B depicts a second cross-sectional view corresponding to the line Y1 in FIG. 12 following wafer flipping and semiconductor substrate removal, according to an embodiment of the invention.

FIG. 15C depicts a third cross-sectional view corresponding to the line Y2 in FIG. 12 following wafer flipping and semiconductor substrate removal, according to an embodiment of the invention.

FIG. 16A depicts a first cross-sectional view corresponding to the line X in FIG. 12 following selective semiconductor layer removal, according to an embodiment of the invention.

FIG. 16B depicts a second cross-sectional view corresponding to the line Y1 in FIG. 12 following selective semiconductor layer removal, according to an embodiment of the invention.

FIG. 16C depicts a third cross-sectional view corresponding to the line Y2 in FIG. 12 following selective semiconductor layer removal, according to an embodiment of the invention.

FIG. 17A depicts a first cross-sectional view corresponding to the line X in FIG. 12 following backside ILD layer formation and planarization, according to an embodiment of the invention.

FIG. 17B depicts a second cross-sectional view corresponding to the line Y1 in FIG. 12 following backside ILD layer formation and planarization, according to an embodiment of the invention.

FIG. 17C depicts a third cross-sectional view corresponding to the line Y2 in FIG. 12 following backside ILD layer formation and planarization, according to an embodiment of the invention.

FIG. 18A depicts a first cross-sectional view corresponding to the line X in FIG. 12 following backside ILD layer patterning for backside contacts, according to an embodiment of the invention.

FIG. 18B depicts a second cross-sectional view corresponding to the line Y1 in FIG. 12 following backside ILD layer patterning for backside contacts, according to an embodiment of the invention.

FIG. 18C depicts a third cross-sectional view corresponding to the line Y2 in FIG. 12 following backside ILD layer patterning for backside contacts, according to an embodiment of the invention.

FIG. 19A depicts a first cross-sectional view corresponding to the line X in FIG. 12 following backside contact formation, according to an embodiment of the invention.

FIG. 19B depicts a second cross-sectional view corresponding to the line Y1 in FIG. 12 following backside contact formation, according to an embodiment of the invention.

FIG. 19C depicts a third cross-sectional view corresponding to the line Y2 in FIG. 12 following backside contact formation, according to an embodiment of the invention.

FIG. 20A depicts a first cross-sectional view corresponding to the line X in FIG. 12 following backside power delivery network (BSPDN) formation, according to an embodiment of the invention.

FIG. 20B depicts a second cross-sectional view corresponding to the line Y1 in FIG. 12 following backside power delivery network (BSPDN) formation, according to an embodiment of the invention.

FIG. 20C depicts a third cross-sectional view corresponding to the line Y2 in FIG. 12 following backside power delivery network (BSPDN) formation, according to an embodiment of the invention.

### DETAILED DESCRIPTION

Illustrative embodiments of the invention may be described herein in the context of illustrative methods for forming source/drain regions for nanosheet transistors, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

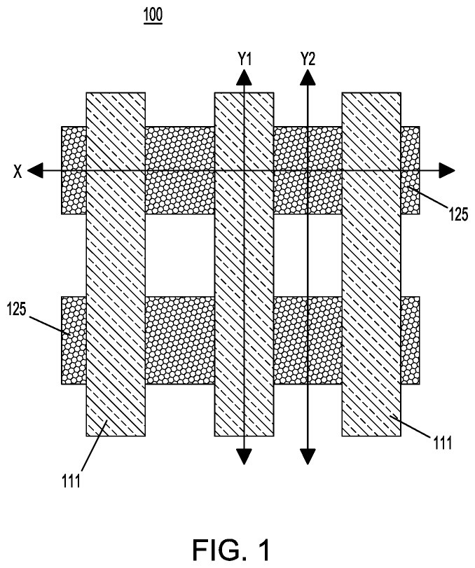

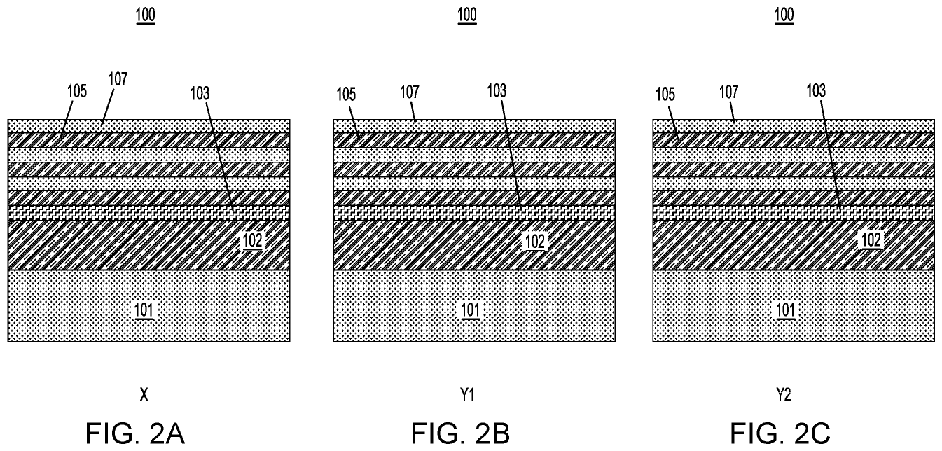

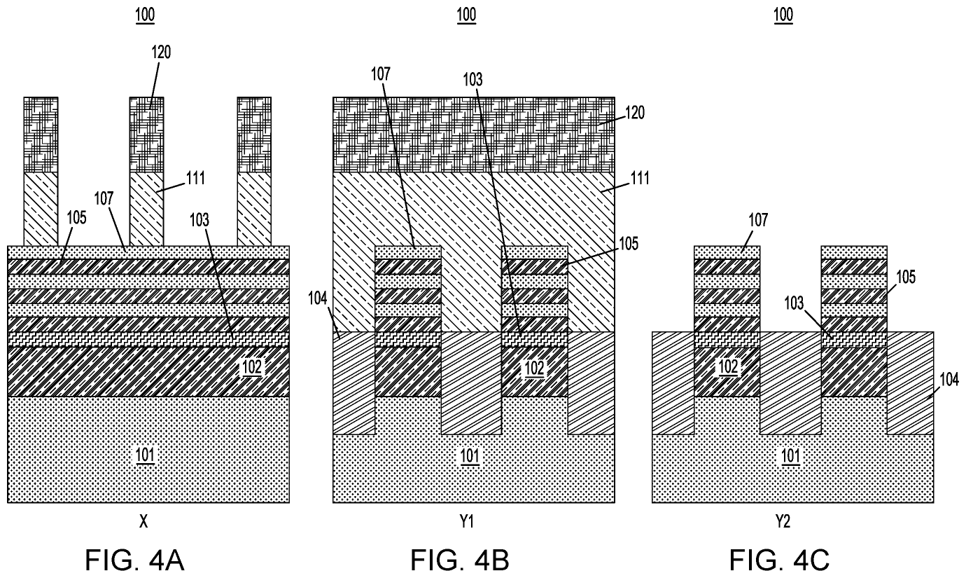

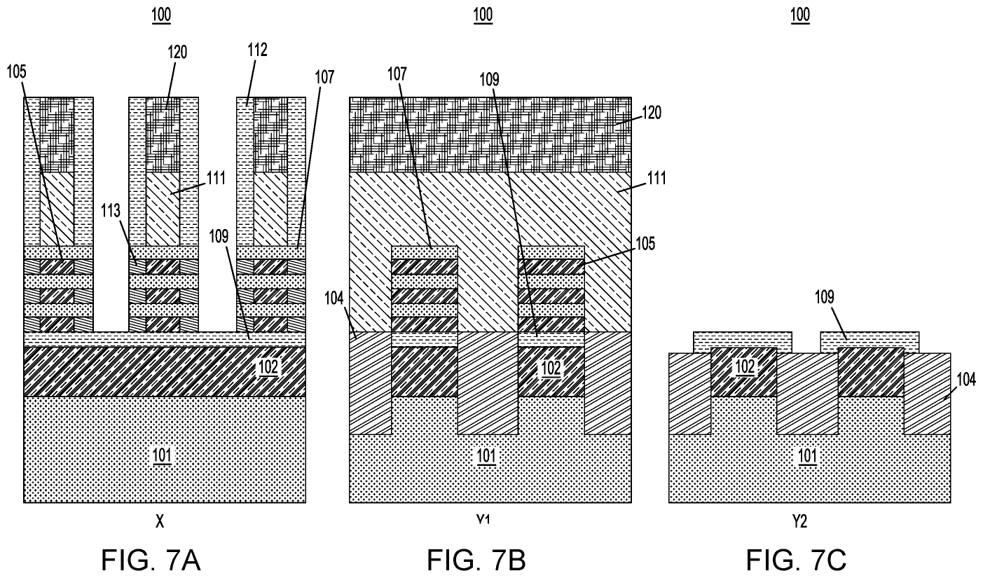

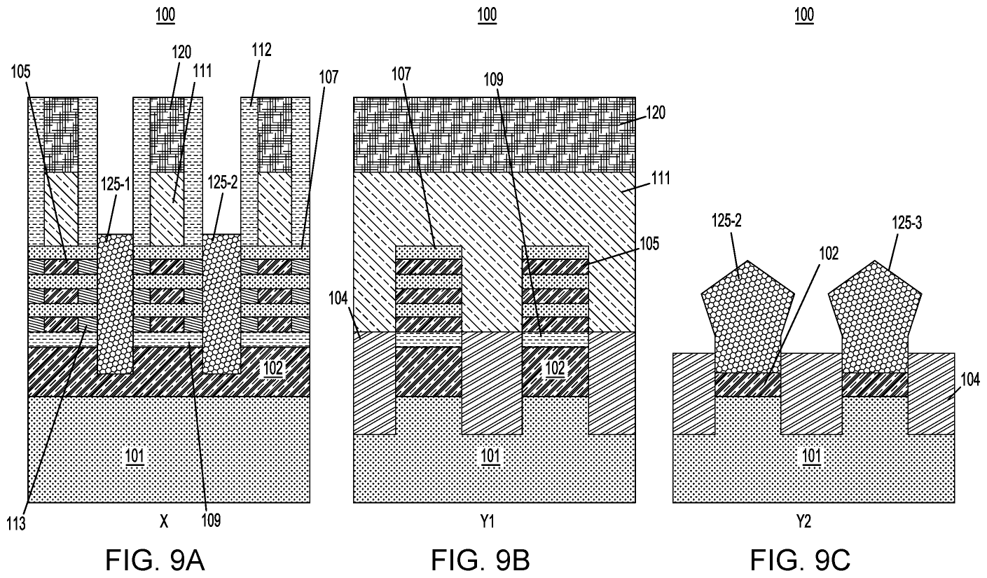

FIG. 1 depicts a top view of a semiconductor structure 100 with lines X, Y1 and Y2 on which the cross-sectional views of FIGS. 2A-11C are based. FIG. 1 illustrates dummy gate portions 111 and source/drain regions 125, which are described in more detail herein in connection with, for example, FIGS. 4A-4C and 9A-9C. Referring to FIG. 1 and to the cross-sectional views in FIGS. 2A, 2B and 2C, which respectively correspond to the lines X, Y1 and Y2 in FIG. 1, a semiconductor structure 100 includes a stacked structure of sacrificial layers 105 and channel layers 107. In an illustrative embodiment, the sacrificial layers 105 comprise silicon germanium (SiGe) and the channel layers 107 comprise silicon. In illustrative embodiments, the sacrificial layers 105 comprise a germanium concentration of about 30% (e.g., SiGe30), but the embodiments are not necessarily limited to SiGe30 for the sacrificial layers 105. The lowermost sacrificial layer is formed on an additional sacrificial layer 103 including, for example, SiGe with a different concentration of germanium than that of the sacrificial layers 105. For example, the additional sacrificial layer 103 has, but is not necessarily limited to, a germanium concentration of about 55% (e.g., SiGe55). As explained in more detail herein, the additional sacrificial layer 103 has a different concentration of germanium than the sacrificial layers 105 so that remaining portions of the additional sacrificial layer 103 can be selectively etched and removed with respect to sacrificial layers 105 when forming bottom dielectric isolation (BDI) layers (see, e.g., FIGS. 7A-7C including BDI layers 109).

Referring to FIGS. 2A-2C, a semiconductor substrate 101 comprises semiconductor material including, but not limited to, silicon, III-V, II-V compound semiconductor materials or other like semiconductor materials. In addition, multiple layers of the semiconductor materials can be used as the semiconductor material of the semiconductor substrate 101. A semiconductor layer 102 is formed on the semiconductor substrate 101. In an illustrative embodiment, the semiconductor layer 102 comprises SiGe (e.g., SiGe30) and the semiconductor substrate 101 comprises silicon.

According to one or more embodiments, the semiconductor layer 102 is epitaxially grown on the semiconductor substrate 101 and the additional sacrificial layer 103 is epitaxially grown on the semiconductor layer 102. The sacrificial layers 105 and channel layers 107 are epitaxially grown in an alternating and stacked configuration on the additional sacrificial layer 103. In either case, a first sacrificial layer 105 is followed by a first channel layer 107 on the first sacrificial layer 105, which is followed by a second sacrificial layer on the first channel layer 107, and so on. As can be understood, the sacrificial and channel layers 105 and 107 are epitaxially grown from their corresponding underlying semiconductor layers.

While three sacrificial layers 105 and three channel layers 107 are shown, the embodiments of the present invention are not necessarily limited to the shown number of sacrificial and channel layers 105 and 107, and there may be more or less layers in the same alternating configuration depending on design constraints. The sacrificial layers 105, as described further herein, are eventually removed and replaced by gate structures.

Although SiGe is described as a sacrificial material for sacrificial layers 105, other materials can be used as long as the sacrificial layers 105 have the property of being able to be removed selectively compared to the material of the channel layers 107.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height of the sacrificial layers 105 can be in the range of about 6 nm to about 15 nm depending on the application of the device. Also, in a non-limiting illustrative embodiment, a height of the channel layers 107 can be in the range of about 6 nm to about 15 nm depending on the desired process and application. In accordance with an embodiment of the present invention, each of the channel layers 107 has the same or substantially the same composition and size as each other, and each of the sacrificial layers 105 has the same or substantially the same composition and size as each other.

As used herein, “frontside or “first side” refers to a side on top of the semiconductor substrate 101 and/or in front of, on top of or in an upward direction from the stacked nanosheet/gate and channel layers of the transistors in the orientation shown in the cross-sectional figures. As used herein, “backside” or “second side” refers to a side below the semiconductor substrate 101 and/or behind, below or in a downward direction from the stacked nanosheet/gate and channel layers of the transistors in the orientation shown in the cross-sectional figures (e.g., opposite the “frontside”).

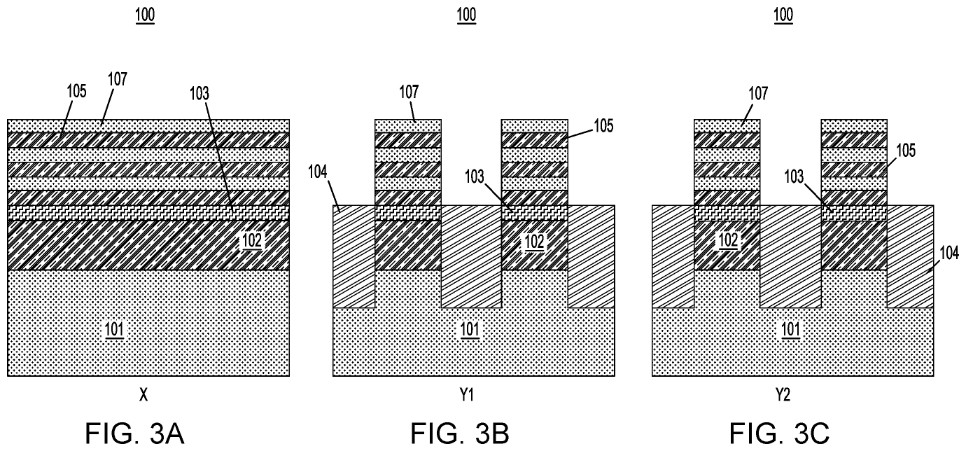

Referring to FIGS. 3A-3C, portions of the nanosheet stacks comprising the sacrificial layers 105 and channel layers 107 are removed, portions of the additional sacrificial layer 103 and of the semiconductor layer 102 are removed and portions of the semiconductor substrate 101 are recessed. Isolation regions 104 (e.g., shallow trench isolation (STI)) regions are formed between the remaining nanosheet stacks, and remaining portions of the additional sacrificial layer 103, the semiconductor layer 102 and the semiconductor substrate 101.

As can be seen in FIGS. 3B and 3C, portions of the semiconductor layer 102 are removed, and portions of the semiconductor substrate 101 are recessed to a lower height. Isolation regions 104 comprising dielectric material fill in the recessed portions of the semiconductor substrate 101 and the vacant areas left by the removal of the portions of the additional sacrificial layer 103 and the semiconductor layer 102. The dielectric material may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

Referring to FIGS. 4A-4C, dummy gate portions 111 are formed on the uppermost channel layers 107 and around the stacked nanosheet configurations of the sacrificial layers 105 and channel layers 107. The dummy gate portions 111 include, but are not necessarily limited to, an amorphous silicon (a-Si) layer. The dummy gate portions 111 are deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer. Hardmask layers 120 are formed on the dummy gate portions 111. The hardmask layers 120 comprise, for example, a nitride such as SiN or other nitride material.

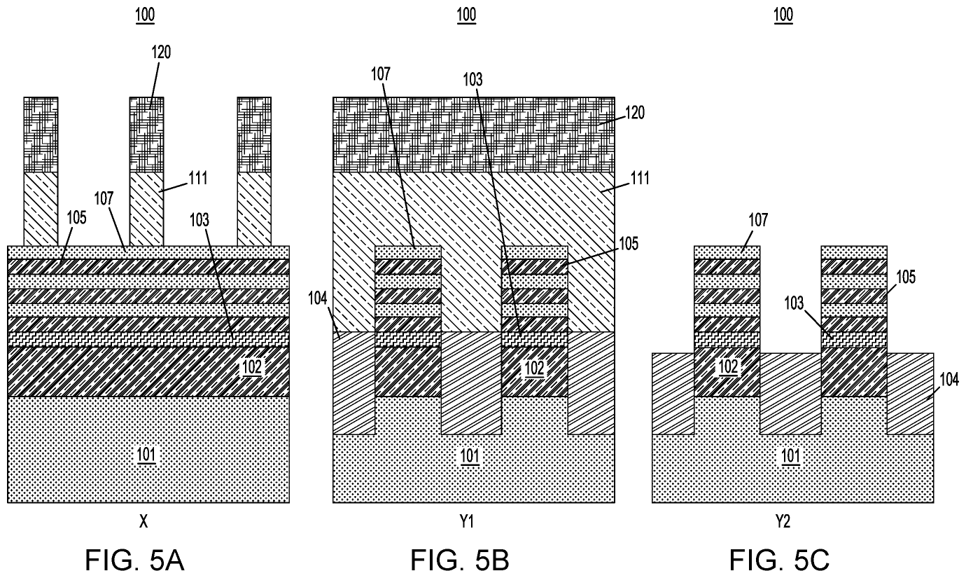

Referring to FIG. 5C, an oxide etch is performed to reduce the height of exposed portions of the isolation regions 104 to a height below the bottom surfaces of the remaining portions of the additional sacrificial layer 103, and below top surfaces of the remaining portions of the semiconductor layer 102. FIGS. 5A and 5B are the same as FIGS. 4A and 4B.

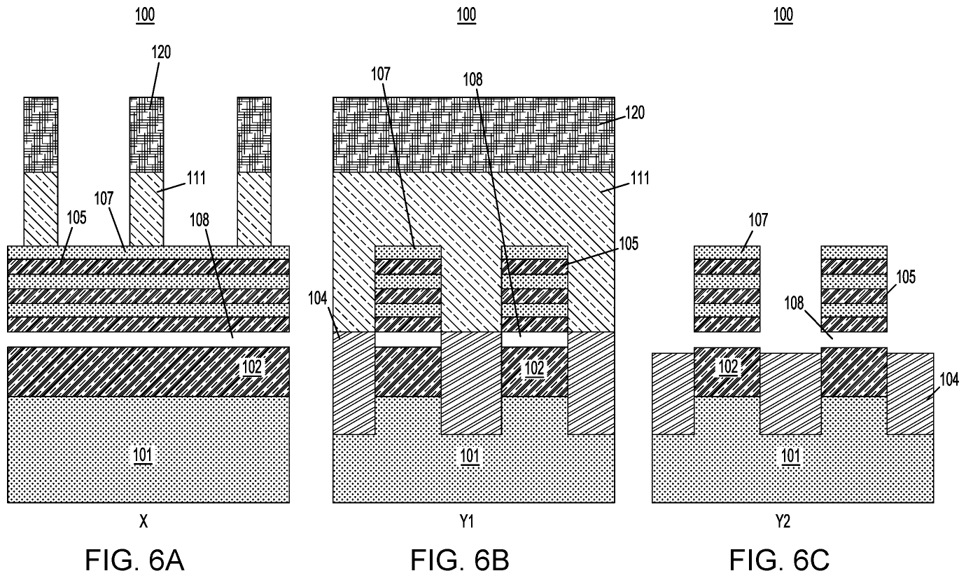

Referring to FIGS. 6A-6C, the remaining portions of the additional sacrificial layer 103 between the lowermost sacrificial layers 105 and the remaining portions of the semiconductor layer 102 are removed using, for example, an aqueous solution containing ammonium hydroxide (NH₄OH) and hydrogen peroxide (H₂O₂) or a gas containing hydrogen fluoride (HF) to selectively etch the portions of the additional sacrificial layer 103 with respect to the portions of the semiconductor layer 102, the sacrificial layers 105 and the channel layers 107. The selective etching removes the remaining portions of the additional sacrificial layer 103 to form vacant areas 108 where the BDI layers 109 will be formed.

Referring to FIGS. 7A-7C, following the removal of the remaining portions of the additional sacrificial layer 103, dielectric material is deposited in place of the remaining portions of the additional sacrificial layer 103 using deposition techniques such as, for example, CVD, PECVD, RFCVD, PVD, ALD, MBD, PLD, and/or LSMCD, followed by an etch back to form the BDI layers 109 on the remaining portions of the semiconductor layer 102 and portions of the isolation regions 104. The BDI layers 109 may comprise, for example, silicon oxide (SiOₓ) (where x is for example, 2, 1.99 or 2.01), silicon oxycarbide (SiOC), SiN, SiON, SiCN, BN, SiBCN, SiOCN or some other dielectric. The BDI layer 109 is under a bottom surface of the lowermost sacrificial layer 105.

Referring to FIG. 7A, gate spacers 112 are formed on sides of the hardmask layers 120 and dummy gate portions 111 by one or more of the deposition techniques noted in connection with deposition of the dummy gate material. The spacer material can comprise for example, one or more dielectrics, including, but not necessarily limited to, SiN, SiON, SiOC, SiCN, BN, SiBN, SiBCN, SiOCN, SiOₓ, and combinations thereof. According to an embodiment, the hardmask layers 120 and gate spacers 112 can be the same material or different materials. The gate spacers 112 can be formed by any suitable techniques such as deposition followed by directional etching. Deposition may include but is not limited to, ALD or CVD. Directional etching may include but is not limited to, reactive ion etching (RIE).

Exposed portions of the stacked sacrificial layers 105 and channel layers 107, which are not under the hardmask layers 120, gate spacers 112 and dummy gate portions 111, are removed using, for example, an etching process, such as RIE, where the hardmask layers 120, gate spacers 112 and dummy gate portions 111 are used as a mask. As can be seen in FIG. 7A, the portions of the stacked structures of sacrificial layers 105 and channel layers 107 under the hardmask layers 120, gate spacers 112 and under the dummy gate portions 111 remain after the etching process, and portions of the sacrificial layers 105 and channel layers 107 in areas that correspond to where source/drain regions will be formed are removed. The etching is stopped at the BDI layer 109. Portions of the top surface of the BDI layer 109 on sides of the stacked structures of sacrificial layers 105 and channel layers 107 are exposed.

Due to, for example, germanium in the sacrificial layers 105, lateral etching of the sacrificial layers 105 can be performed selective to the channel layers 107, such that the side portions of the sacrificial layers 105 can be removed to create vacant areas to be filled in by inner spacers 113. The material of the inner spacers 113 can comprise, but is not necessarily limited to, a nitride, such as, SiN, SiON, SiCN, BN, SiBN, SiBCN or SiOCN. Gate spacers 112 are positioned on the nanosheet stacks on opposite lateral sides of the dummy gate portions 111. In an illustrative embodiment, the gate spacers 112 are formed from the same or similar material to that of the inner spacers 113. Like the gate spacers 112, the inner spacers 113 can be formed by any suitable techniques such as deposition followed by directional etching.

In accordance with an illustrative embodiment, exposed side surfaces of the channel layers 107, which comprise, for example, silicon, are exposed to arsine, which poisons the side surfaces with arsenic. As a result, in a subsequent epitaxial growth process as described further herein, epitaxial nucleation from the exposed side surfaces of the channel layers 107 is delayed. The surfaces have a <110> orientation. Multiple nucleation surfaces formed by each of the channel layers 107 results in stacking faults during source/drain epitaxial growth. Poisoning the side surfaces with arsenic prevents or delays epitaxial growth from the side surfaces such that the stacking faults are prevented or reduced. As explained further herein, the embodiments provide for bottom-up growth of source/drain regions to limit or prevent the stacking faults and the exposure of the side surfaces of the channel layers 107 to arsine is optional.

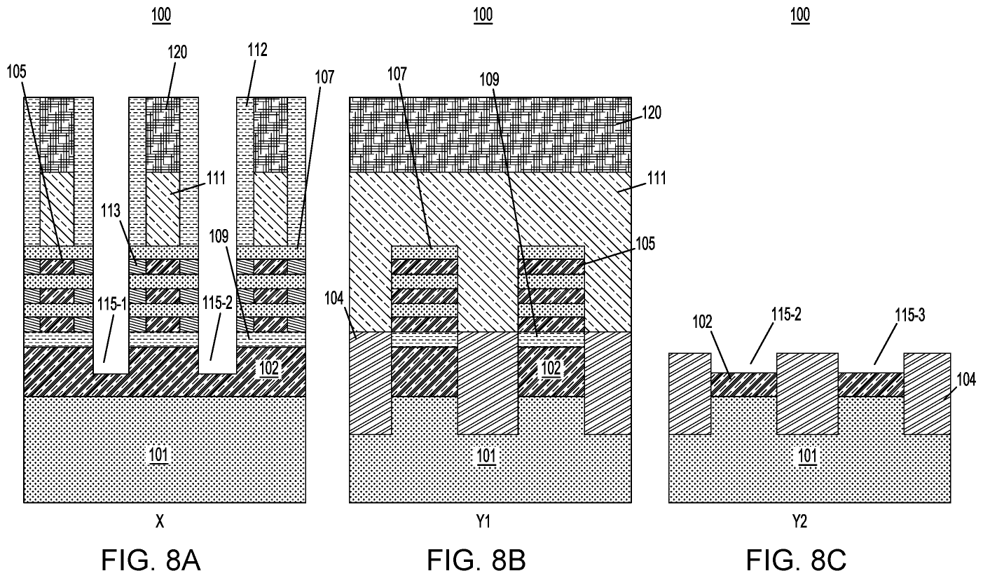

Referring to FIGS. 8A-8C, exposed portions of the BDI layer 109 between the stacked structures of sacrificial layers 105 and channel layers 107 are removed in a first removal process. Following removal of the exposed portions of the BDI layer 109 between the stacked structures of sacrificial layers 105 and channel layers 107, underlying portions of the semiconductor layer 102 are removed, such that portions of the semiconductor layer 102 are recessed to create openings (also referred to herein as “trenches”) 115-1, 115-2 and 115-3 (collectively “trenches 115”) in the semiconductor layer 102. The semiconductor layer 102 can be etched using, for example, Tetramethyl ammonium hydroxide (TMAH) solution, to selectively remove SiGe having a relatively higher percentage of germanium, or CF₄ gas to selectively remove SiGe having a relatively lower percentage of germanium. As can be seen, the exposed portions of the semiconductor layer 102 are recessed below the bottom surfaces of the remaining portions of the BDI layer 109 and below top surfaces of the isolation regions 104.

Referring to FIGS. 9A-9C, epitaxial source/drain regions 125-1, 125-2 and 125-3 (collectively “source/drain regions 125”) are grown from the exposed portions of the semiconductor layer 102 in the trenches 115 in a bottom-up epitaxial growth process. The process is referred to as a bottom-up epitaxial growth process because epitaxial growth occurs at a faster rate from the bottom surfaces of the portions of the semiconductor layer 102 in the trenches 115 than from the side surfaces of the channel layers 107. For example, epitaxial material from the <100> orientation surfaces of the semiconductor layer 102 nucleates faster and has a faster growth rate than from the <110> orientation surfaces of the channel layers 107. This difference in growth is increased when the side surfaces of the channel layers 107 are exposed to arsine.

As can be seen, a bottom portions of the source/drain regions 125 are disposed in and fill the trenches 115, extend through the BDI layer 109 and are positioned between the stacked structure of sacrificial layers 105 and channel layers 107. The isolation regions 104 are disposed around one or more sides of the bottom portions of the source/drain regions 125. Side surfaces of respective ones of the channel layers 107 contact a side surface at least one adjacent source/drain region 125. The top surfaces of the source/drain regions 125 are above the top surfaces of uppermost ones of the channel layers 107.

According to a non-limiting embodiment of the present invention, the conditions of the epitaxial growth process for the source/drain regions 125 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr. In the case of n-type FETS (nFETs), the source/drain regions 125 can comprise silicon doped with n-type dopants including, for example, phosphorus (P), arsenic (As) and antimony (Sb). In the case of p-type FETS (pFETs), the source/drain regions 125 can comprise silicon doped with n-type dopants including, for example, boron (B), boron fluoride (BF₂), gallium (Ga), indium (In), and thallium (Tl).

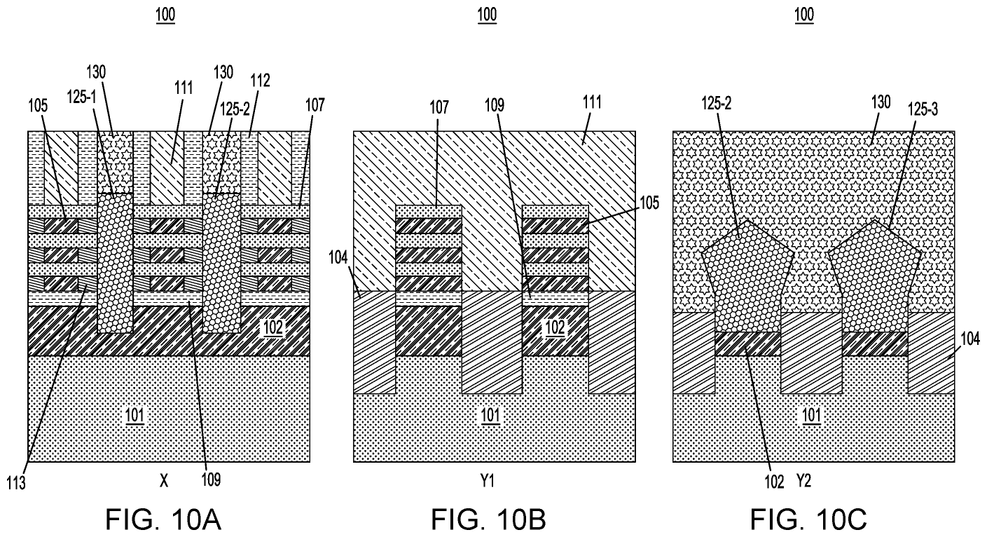

Referring to FIGS. 10A-10C, an inter-layer dielectric (ILD) layer 130 is deposited to fill in portions on and around the source/drain regions 125. The ILD layer 130 is deposited using deposition techniques such as, for example, CVD, PECVD, RFCVD, PVD, ALD, MBD, PLD, and/or LSMCD, followed by a planarization process, such as, chemical mechanical planarization (CMP) to remove excess portions of the ILD layer 130 deposited on top of the hardmask layers 120 and gate spacers 112, and to remove the hardmask layers 120 and portions of the gate spacers 112 to expose the dummy gate portions 111. The ILD layer 130 may comprise, for example, SiOx, SiOC, SiOCN or some other dielectric.

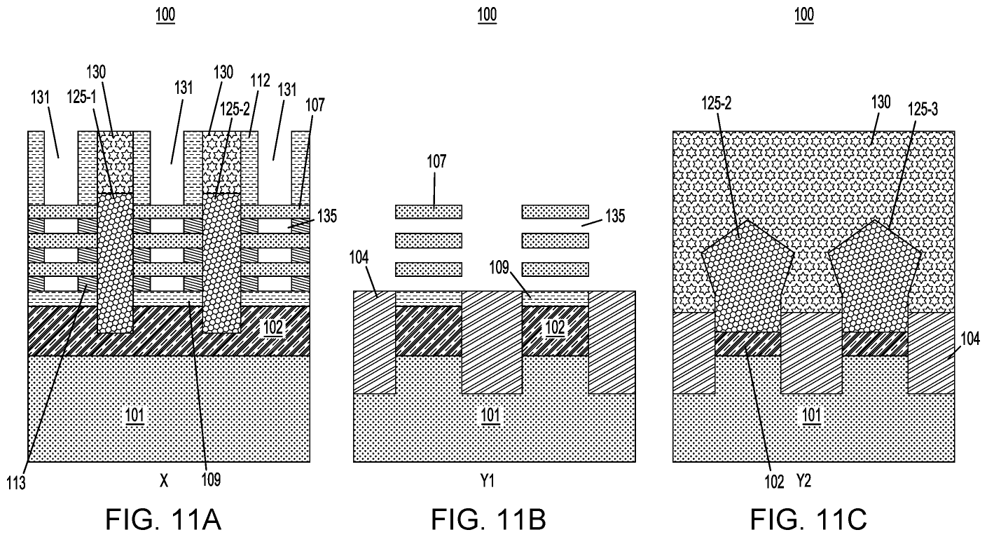

Referring to FIGS. 11A-11C, the dummy gate portions 111 are selectively removed to create vacant areas 131 where gate structures will be formed in place of the dummy gate portions 111. The selective removal can be performed using, for example, hot ammonia to remove a-Si. In addition, the sacrificial layers 105 are selectively removed to create vacant areas where gate structures will be formed in place of the sacrificial layers 105. The sacrificial layers 105 are selectively removed with respect to the channel layers 107. The selective removal can be performed using, for example, a dry HCl etch.

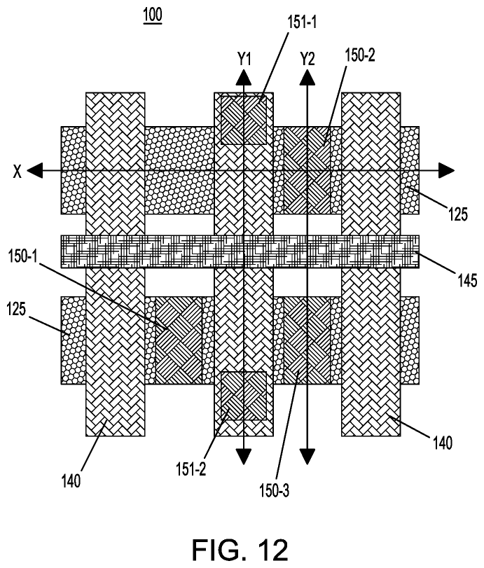

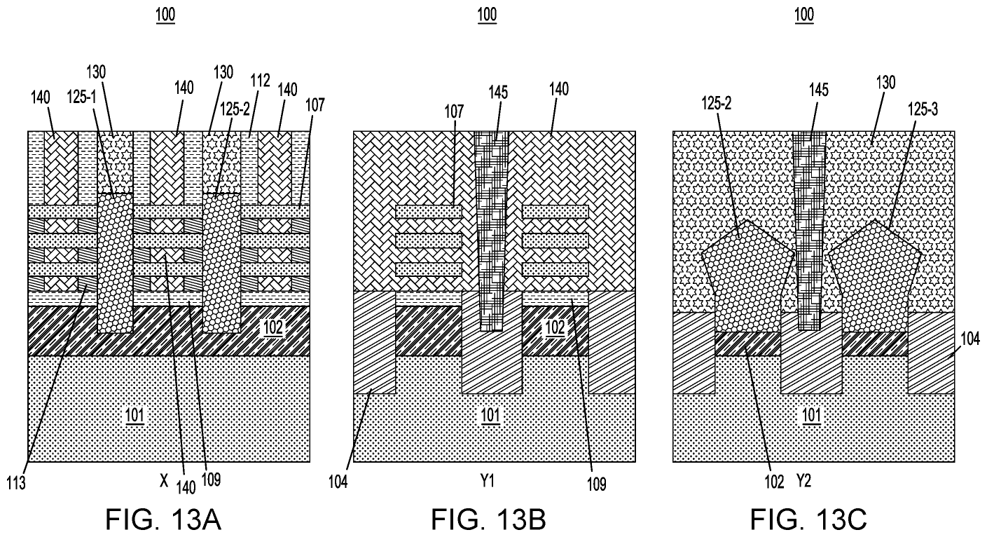

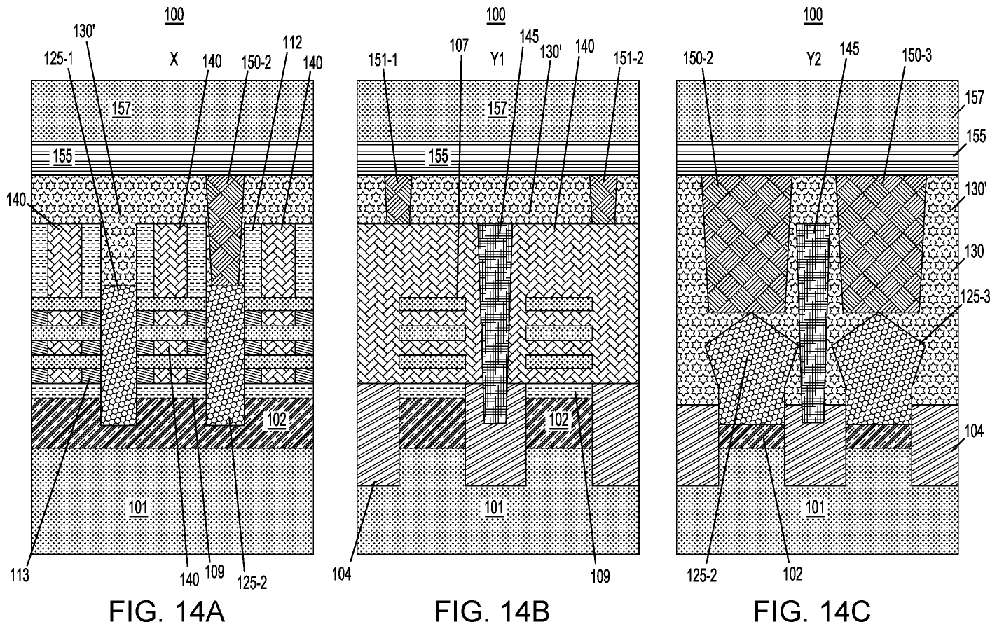

FIG. 12 depicts a top view of the semiconductor structure 100 with lines X, Y1 and Y2 on which the cross-sectional views of FIGS. 13A-20C are based. FIG. 12 illustrates gate regions 140, a gate cut portion 145, frontside source/drain contacts 150-1, 150-2 and 150-3 (collectively “frontside source/drain contacts 150”) and gate contacts 151-1 and 151-2 (collectively “gate contacts 151”), which are described in more detail herein in connection with, for example, FIGS. 13A-13C and 14A-14C.

Referring to FIGS. 13A-13C, following removal of the dummy gate portions 111 and sacrificial layers 105, the channel layers 107 are suspended, and gate regions 140, including, for example, gate and dielectric portions are formed in the vacant portions left by removal of the dummy gate portions 111, and the sacrificial layers 105. In illustrative embodiments, each gate region 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate regions 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Part of gate region 140 between the nanosheet stacks comprising the channel layers 107 and gate regions 140, and between the source/drain regions 125 is removed down to an isolation region 104, and part of the exposed portion of the isolation region 104 is also removed to form a trenches in which dielectric material is deposited to form gate cut portion 145. The part of the gate region 140 is etched using, for example, RIE. The exposed portion of the isolation region 104 is etched using, for example, RIE. The dielectric material of the gate cut portion 145 is deposited using deposition techniques such as, for example, CVD, PECVD, RFCVD, PVD, ALD, MBD, PLD, and/or LSMCD, followed by a planarization process, such as, CMP to remove excess portions of the dielectric material deposited on top of the gate region 140. The dielectric material of the gate cut portion 145 may comprise, but is not necessarily limited to, SiN, SiC, SiON, SiOC, SiCN, BN, SiBN, SiBCN, SiOCN, SiOₓ or some other dielectric.

Referring to FIGS. 14A-14C, additional ILD material is deposited to form an additional ILD layer 130′ on top of the ILD layer 130. Then, frontside source/drain contacts 150-1 (shown in top view in FIGS. 12), 150-2 and 150-3 are formed in the ILD layers 130 and 130′. In forming the frontside source/drain contacts 150, openings are formed through portions of the ILD layers 130 and 130′. The openings expose portions the source/drain regions 125 on which the frontside source/drain contacts 150 are to be formed. According to an embodiment, masks are formed on parts of the additional ILD layer 130′, and exposed portions of the ILD layers 130 and 130′ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the openings to form the frontside source/drain contacts 150. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the additional ILD layer 130′. Frontside source/drain contacts 150 may be used in addition to backside source/drain contacts as explained further herein in order to fully strap the source/drain regions 125.

The frontside source/drain contacts 150-2 and 150-3 contact respective ones of the source/drain regions 125-2 and 125-3. The frontside source/drain contacts 150 extend through the ILD layers 130 and 130′ to land on and contact the corresponding source/drain regions 125.

Frontside gate contacts 151-1 and 151-2 (collectively “frontside gate contacts 151”) are formed through the additional ILD layer 130′ to land on and contact a corresponding gate region 140 (may also be referred to as a gate structure). The process and materials used for forming the frontside gate contacts 151 are similar to those used for forming the frontside source/drain contacts 150. Frontside BEOL interconnects 155 are formed on the additional ILD layer 130′ including the frontside source/drain contacts 150 and the frontside gate contacts 151. As can be seen, the frontside source/drain contacts 150 and the frontside gate contacts 151 contact the frontside BEOL interconnects 155. A carrier wafer 157 is bonded to the frontside BEOL interconnects 155. The frontside BEOL interconnects 155 include various BEOL interconnect structures which may electrically connect to the frontside source/drain contacts 150 and the frontside gate contacts 151. The carrier wafer 157 may be formed of materials similar to that of the semiconductor substrate 101, and may be formed over the frontside BEOL interconnects 155 using a wafer bonding process, such as dielectric-to-dielectric bonding.

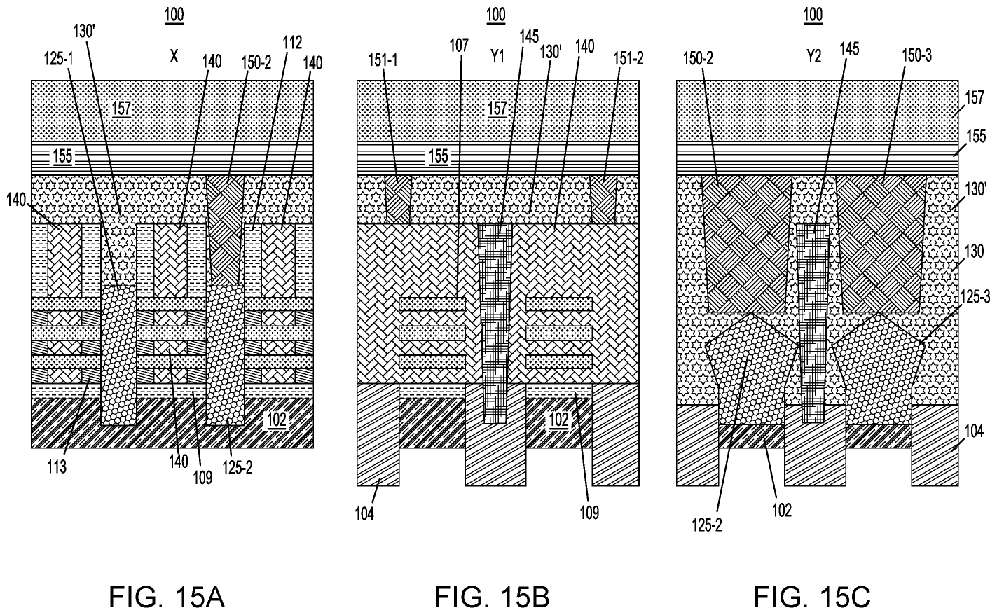

Referring to FIGS. 15A-15C, using the carrier wafer 157, the semiconductor structure 100 may be “flipped” (e.g., rotated 180 degrees) so that the structure is inverted. In addition, the semiconductor substrate 101 is removed from the backside of the semiconductor structure 100. The removal process, which comprises etching of the semiconductor substrate 101, stops at the semiconductor layer 102 and the isolation regions 104. For example, the semiconductor substrate 101 is selectively etched with an etchant that selectively etches silicon with respect to a material of the semiconductor layer 102 (e.g., SiGe) and a material of the isolation regions 104.

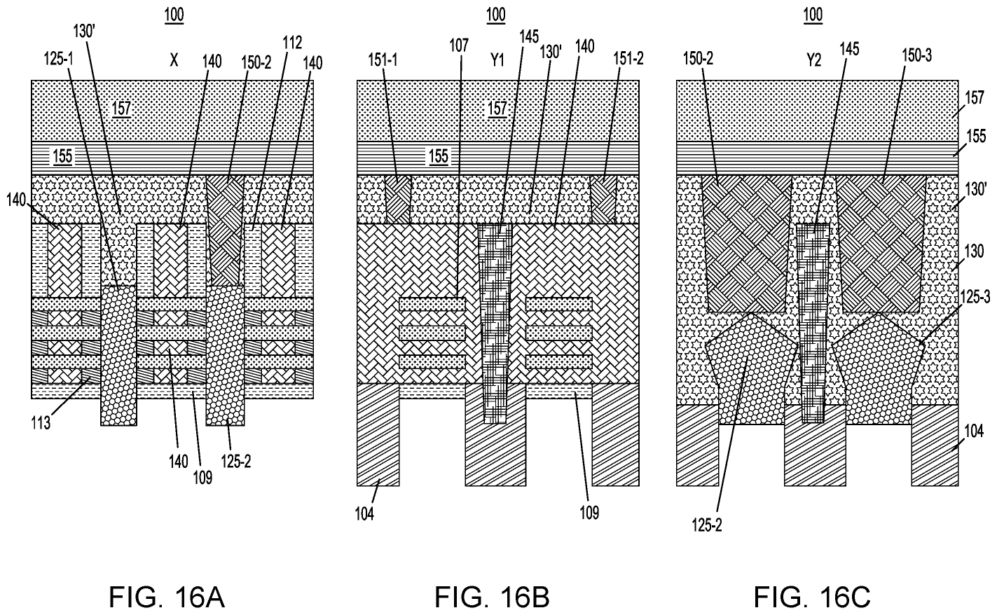

Referring to FIGS. 16A-16C, the semiconductor layer 102 is selectively removed from the semiconductor structure 100 with respect to the isolation regions 104 (e.g., STI regions), BDI layers 109 and source/drain regions 125. As shown in FIGS. 16A-16C, the semiconductor layer 102 is removed, wherein portions of the isolation regions 104, BDI layers 109, and the source/drain regions 125 are exposed. Etching processes for removal of the semiconductor layer 102 include, for example, IBE by Ar/CHF3 based chemistry.

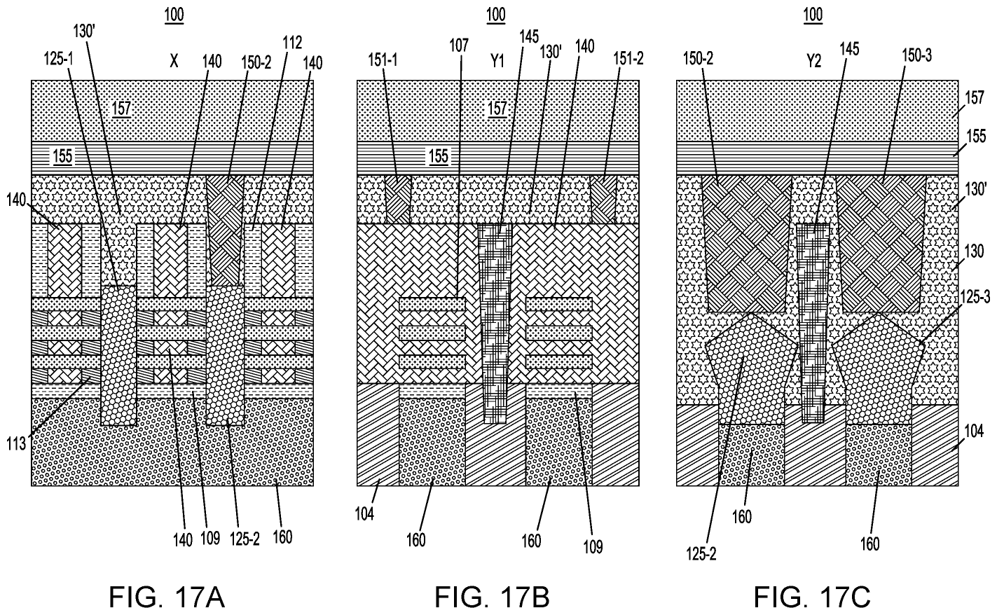

Referring to FIGS. 17A-17C, a backside ILD layer 160 is deposited to fill in areas formerly occupied by the semiconductor layer and part of the semiconductor substrate 101. The backside ILD layer 160 is deposited using deposition techniques such as, for example, CVD, PECVD, RFCVD, PVD, ALD, MBD, PLD, and/or LSMCD, followed by a planarization process, such as, CMP to remove excess portions of the backside ILD layer 160 deposited on top of the isolation regions 104 so that the backside ILD layer 160 is coplanar with surfaces of the isolation regions 104. The backside ILD layer 160 may comprise, for example, SiOx, SiOC, SiOCN or some other dielectric.

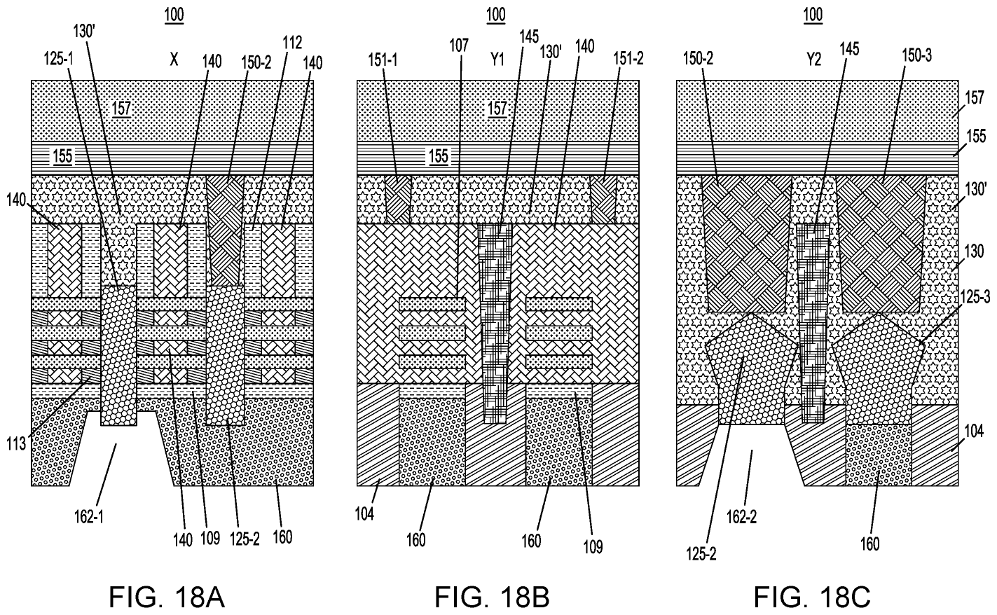

Referring to FIGS. 18A-18C, openings 162-1 and 162-2 are formed in portions of the backside ILD layer 160 to expose portions of the source/drain regions 125-1 and 125-2 on which backside source/drain contacts are to be formed. According to an embodiment, masks are formed on parts of the backside ILD layer 160, and exposed portions of the backside ILD layer 160 corresponding to where the openings 162-1 and 162-2 are to be formed are removed using, for example, a dry etching process using a RIE or IBE process, a wet chemical etch process or a combination of these etching processes. A dry etch may be performed using a plasma. Such wet or dry etch processes include, for example, IBE by Ar/CHF3 based chemistry.

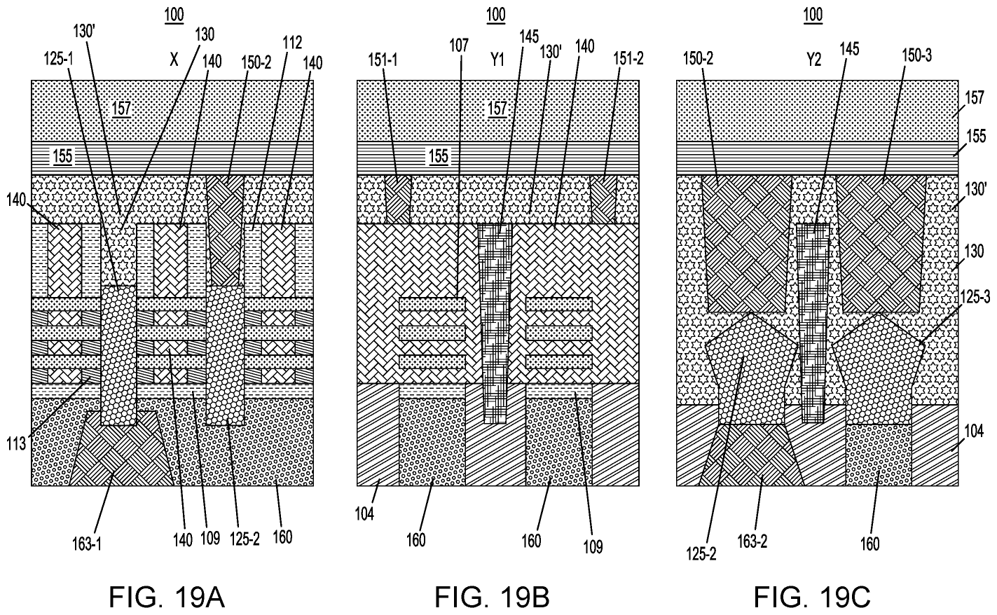

Referring to FIGS. 19A-19C, backside source/drain contacts 163-1 and 163-2 are formed in the backside ILD layer 160 in the openings 162-1 and 162-2. Metal layers are deposited in the openings 162-1 and 162-2 to form the backside source/drain contacts 163-1 and 163-2. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 160.

The backside source/drain contacts 163-1 and 163-2 contact respective backsides of the source/drain regions 125-1 and 125-2. The backside source/drain contacts 163-1 and 163-2 extend through a portion of the backside ILD layer 160 to land on and contact the backsides of the corresponding source/drain regions 125-1 and 125-2.

As can be seen in FIG. 19A, bottom portions of the source/drain regions 125-1 and 125-2 are disposed in the backside ILD layer 160 and through the BDI layer 109 into the backside ILD layer 160. The backside ILD layer 160 is below the lowermost surfaces of the stacked structures of the gate regions 140 and channel layers 107. For example, the backside ILD layer 160 is below the bottom surfaces of the lowermost gate regions 140.

As shown in FIG. 19C, isolation regions 104 are disposed around multiple sides of bottom portions of the source/drain regions 125-2 and 125-3. The backside source/drain contacts 163-1 and 163-2 are disposed in the backside ILD layer 160 on the bottom portions of the source/drain regions 125-1 and 125-2. In at least one embodiment, frontside source/drain contact 150-2 is disposed on a surface of top portion of the source/drain region 125-2 opposite to the bottom portion of the source/drain region 125-2 on which the backside source/drain contact 163-2 is disposed.

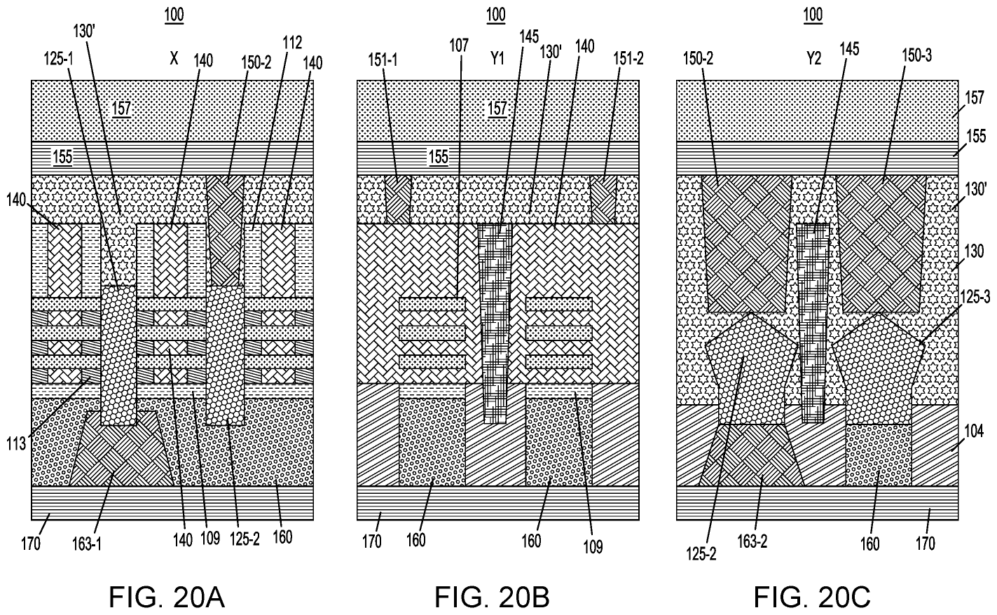

Referring to FIGS. 20A-20C, backside power delivery network (BSPDN) layers 170 (also referred to herein as backside interconnects) are formed on the backside ILD layer 160 and on the backside source/drain contacts 163-1 and 163-2. The BSPDN layers 170 include various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits. The backside source/drain contacts 163-1 and 163-2 are connected to the BSPDN.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures to prevent or at least reduce multiple <110> orientation nucleation surfaces formed by each of the channel layers 107. In the illustrative embodiments, the source/drain epitaxial regions are grown from the semiconductor layer 102 in a bottom-up epitaxial growth process from <100> orientation nucleation surfaces, thereby reducing stacking faults during source/drain epitaxy that would occur from epitaxial growth from side surfaces of the channel layers 107. Nucleation from the <100> orientation of the semiconductor layer 102 occurs at a faster rate than nucleation from the <110> orientation surfaces. In addition, to further ensure the majority or all growth from the semiconductor layer 102, some embodiments expose the side surfaces of the channel layers 107 from which epitaxial growth would occur to arsine to poison the side surfaces with arsenic. As a result, epitaxial growth from the side surfaces of the channel layers 107 is prevented or considerably slowed down so that it has little or no effect on the resulting source/drain regions.

As an additional advantage, the embodiments generate source/drain regions well below bottom surfaces of the stacked gate structures and channel layers of the nanosheet transistors. Since the embodiments use, for example, a semiconductor layer 102 (e.g., SiGe30) from which source/drain regions are epitaxially grown in a deep epitaxial growth process (e.g., from within trenches in the semiconductor layer 102 below the BDI layer) backside source/drain contact placeholders are not required and there is no need for placeholder removal steps prior to forming backside source/drain contacts. In more detail, since the bottom surfaces of the source/drain regions are spaced away from bottom structures of the nanosheet stacks, and backside source/drain contacts directly connect to backside surfaces of the source/drain regions, protective dielectric liners which would normally prevent backside source/drain contacts from shorting to gate structures can be omitted.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a stacked structure comprising a plurality of gate structures alternately stacked with a plurality of channel layers; and
at least one epitaxial source/drain region disposed on a side of the stacked structure;
wherein the stacked structure is disposed on at least one dielectric layer; and
wherein a portion of the at least one epitaxial source/drain region is disposed in the at least one dielectric layer.

2. The semiconductor device of claim 1, further comprising an additional dielectric layer on the at least one dielectric layer, wherein the stacked structure is further disposed on the additional dielectric layer, and the at least one epitaxial source/drain region is disposed through the additional dielectric layer into the at least one dielectric layer.

3. The semiconductor device of claim 1, wherein a shallow trench isolation region is disposed around one or more sides of the portion of the at least one epitaxial source/drain region.

4. The semiconductor device of claim 1, further comprising a source/drain contact disposed in the at least one dielectric layer and on the portion of the at least one epitaxial source/drain region.

5. The semiconductor device of claim 4, wherein the source/drain contact is connected to a backside power delivery network.

6. The semiconductor device of claim 1, wherein side surfaces of respective ones of the plurality of channel layers contact a side surface of the at least one epitaxial source/drain region.

7. The semiconductor device of claim 6, wherein at least a portion of the side surfaces of the respective ones of the plurality of channel layers comprise arsenic.

8. The semiconductor device of claim 1, wherein the at least one epitaxial source/drain region is disposed in the at least one dielectric layer at a depth below a lowermost surface of the stacked structure.

9. The semiconductor device of claim 1, further comprising a source/drain contact disposed on a surface of an additional portion of the at least one epitaxial source/drain region located opposite to the portion of the at least one epitaxial source/drain region.

10. A semiconductor device comprising:
a first nanosheet structure comprising a first plurality of gate structures alternately stacked with a first plurality of channel layers;
a second nanosheet structure comprising a second plurality of gate structures alternately stacked with a second plurality of channel layers; and
at least one epitaxial source/drain region disposed between the first and second nanosheet structures;
wherein the first and second nanosheet structures are disposed on at least one dielectric layer; and
wherein a portion of the at least one epitaxial source/drain region is disposed in the at least one dielectric layer.

11. The semiconductor device of claim 10, further comprising an additional dielectric layer on the at least one dielectric layer, wherein the first and second nanosheet structures are further disposed on the additional dielectric layer, and the at least one epitaxial source/drain region is disposed through the additional dielectric layer into the at least one dielectric layer.

12. The semiconductor device of claim 10, further comprising a source/drain contact disposed in the at least one dielectric layer and on the portion of the at least one epitaxial source/drain region.

13. The semiconductor device of claim 12, wherein the source/drain contact is connected to a backside power delivery network.

14. The semiconductor device of claim 10, wherein side surfaces of respective ones of the plurality of first and second channel layers contact side surfaces of the at least one epitaxial source/drain region.

15. The semiconductor device of claim 14, wherein at least a portion of the side surfaces of the respective ones of the plurality of first and second channel layers comprise arsenic.

16. A method comprising:
forming a stacked structure comprising a plurality of sacrificial semiconductor layers alternately stacked with a plurality of channel layers, wherein the stacked structure is formed on a semiconductor layer comprising a surface with a designated crystal orientation; and
growing at least one epitaxial source/drain region on a side of the stacked structure from an exposed portion of the semiconductor layer in a bottom-up epitaxial growth process.

17. The method of claim 16, wherein the semiconductor layer comprises silicon germanium, and the designated crystal orientation comprises a <100> orientation.

18. The method of claim 16, further comprising exposing side surfaces of respective ones of the plurality of channel layers to arsine prior to growing the at least one epitaxial source/drain region.

19. The method of claim 16, further comprising removing part of the semiconductor layer to form a trench in the semiconductor layer, wherein the trench comprises the exposed portion of the semiconductor layer from which the at least one epitaxial source/drain region is grown, and extends to a depth below and spaced apart from a lowermost surface of the stacked structure.

20. The method of claim 19, wherein a dielectric layer is formed on the semiconductor layer, and the method further comprises removing a portion of the dielectric layer to expose the part of the semiconductor layer to be removed to form the trench.
